(19) United States
(12) Patent Application Publication
(10) Pub. No.: US 2017/0200847 A1
(43) Pub. Date: Jul. 13, 2017

(54) PHOTOVOLTAIC DEVICE AND DISPLAY EQUIPMENT

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jianjie WU, Beijing (CN); Lili CHEN, Beijing (CN); Ruijun DONG, Beijing (CN); Chenru WANG, Beijing (CN); Wei SUN, Beijing (CN); Guangquan WANG, Beijing (CN)

(21) Appl. No.: 15/252,713

(22) Filed: Aug. 31, 2016

(30) Foreign Application Priority Data
Jan. 13, 2016 (CN) 201610021236.2

(51) Int. Cl. H01L 31/054; H01L 31/12; H01L 31/046

(52) U.S. Cl. CPC H01L 31/0543; H01L 31/046; H01L 31/125

(57) ABSTRACT

A photovoltaic device and display equipment are provided. The photovoltaic device includes at least one photoelectric conversion sheet and a light guide plate, the at least one photoelectric conversion sheet arranged at a light exiting face side of the light guide plate.

### TECHNICAL FIELD

The present disclosure relates to a photovoltaic device and display equipment.

### BACKGROUND

Since the functions of the electronic equipments are getting increasingly abundant, the electronic equipments are subjected to quick power consumption and thus need to be charged frequently which influencing its service life. In order to improve the endurance power of an electronic equipment, taking a mobile phone as an example: the prior art proposes to assembly a photoelectric conversion sheet on the rear cover of the mobile phone to transform optical energy into electric energy using the photoelectric conversion sheet, so as to charge the secondary battery of the mobile electronic equipment and thereby improve the endurance power of the mobile electronic equipment. However, the rear cover of the mobile electronic equipment is always made from metal, plastics and similar nontransparent materials, in prior art, for the purpose of enabling the photoelectric conversion sheet to receive sunlight, it is usually required to open a window at the rear cover of the mobile phone and then embed the photoelectric conversion sheet into the window. The above manner destroys the wholeness of the rear cover of the electronic equipment, leading to a bad appearance effect. At the same time, due to the electrode grid wires presented on the surface of the conventional photoelectric conversion sheets, the appearance effect is further influenced. In addition, the prior art requires the provision of an embed engagement structure which is complicated and goes against the reduction of the thickness of the electronic equipment.

### SUMMARY

An embodiment of the disclosure provides a photovoltaic device comprising at least one photoelectric conversion sheet and a light guide plate, the at least one photoelectric conversion sheet arranged at a light exiting face side of the light guide plate.

In some examples, the photovoltaic device comprises two photoelectric conversion sheets provided at two opposite primary surface sides of the light guide plate, respectively.

In some examples, the photovoltaic device comprises one photoelectric conversion sheet provided at one of the primary surface sides of the light guide plate.

In some examples, the photovoltaic device further comprises a light emitting source provided at a light incident side of the light guide plate.

In some examples, the photovoltaic device further comprises a light-emitting diode connected with the photoelectric conversion sheet.

In some examples, the photoelectric conversion sheet comprises a n-type layer, a p-n junction, a p-type layer, a reflective layer and an electrode arranged on the light guide plate in this order; the electrode and the n-type layer are connected with the light-emitting diode through a conductive line, respectively.

In some examples, the reflective layer is a metal reflective film.

In some examples, the electrode is a metal electrode.

In some examples, a material for the photoelectric conversion sheet is a semiconductor material or an inorganic compound molecular material or a nano-crystalline material.

In some examples, the light guide plate is provided with multiple dot structures at its surface, so that the incident light transmits into the photoelectric conversion sheet along the dot structures.

In some examples, a material for the light guide plate is a lithium niobate material.

An embodiment of the disclosure provides a display equipment comprising any photovoltaic device as mentioned above.

In some examples, the photovoltaic device is provided inside the display equipment and a light incident side of the light guide plate of the photovoltaic device is exposed.

### BRIEF DESCRIPTION OF THE DRAWINGS

In the following, a brief introduction will be made to the drawings of the embodiments of present invention so as to describe the embodiments more clearly, and obviously, the drawings described below only relate to some of the embodiments of the present invention, rather than limitation of the present invention.

FIG. 1 is a structural schematic view of a photovoltaic device of a first embodiment of the present disclosure;

FIG. 2 is a schematic view illustrating an operation state of a photovoltaic device of the first embodiment of the present disclosure;

FIG. 3 is a structural schematic view of the photovoltaic device of a second embodiment of the present disclosure; and

FIG. 4 is a schematic view of display equipment provided by an embodiment of the present disclosure.

### DETAILED DESCRIPTION

For the purpose of making the purpose, the technical solution and its advantages of the embodiment of present invention even more clear, a clear and complete description will be made about the technical solution of the embodiment of present invention in conjunction with the drawings of the embodiment of present invention. Apparently, the described embodiments are only part of the embodiments of the present invention, rather than all of the embodiments. Based on the described embodiments of present invention, all the other embodiments obtained by the ordinary skilled person in this art without creative endeavors belong to the protective scope of the present invention.

To be specified, in the description of the present disclosure, unless stated otherwise, “a plurality of” means two or more; the terms “upper”, “lower”, “left”, “right”, “inner”, “outer”, “front end”, “rear end”, “head”, “tail” and the like refer to such orientation or positional relationships that are illustrated based on those illustrated in the drawings, or alternatively, are conventional orientation or positional relationships in which the disclosed products are placed, these terms are used merely for the purpose of facilitating and simplifying the description of the present disclosure, rather than indicating or suggesting that the referred devices or elements must have specific orientations, are designed and operated in a specific orientation, and thus cannot be understood as restriction upon the present disclosure. Furthermore, the terms “first”, “second”, “third”, and the like are used only for description, instead of being appreciated as indication or suggestion of relative importance.

In the description of the present disclosure, it need to note that, in the description of the present invention, unless otherwise specified or limited explicitly, the terms “mount”, “couple”, “connect” and so on should be understood in a broad sense, for example, they may be a detachable connection, or an integral connection; may be a mechanical connection, or may be an electrical connection; may be a direct connection, and also may be an indirect connection through intermediate medium. The ordinary skilled in this art could appreciate the specific meaning of the above terms in the present disclosure according to specific situations.

### First Embodiment

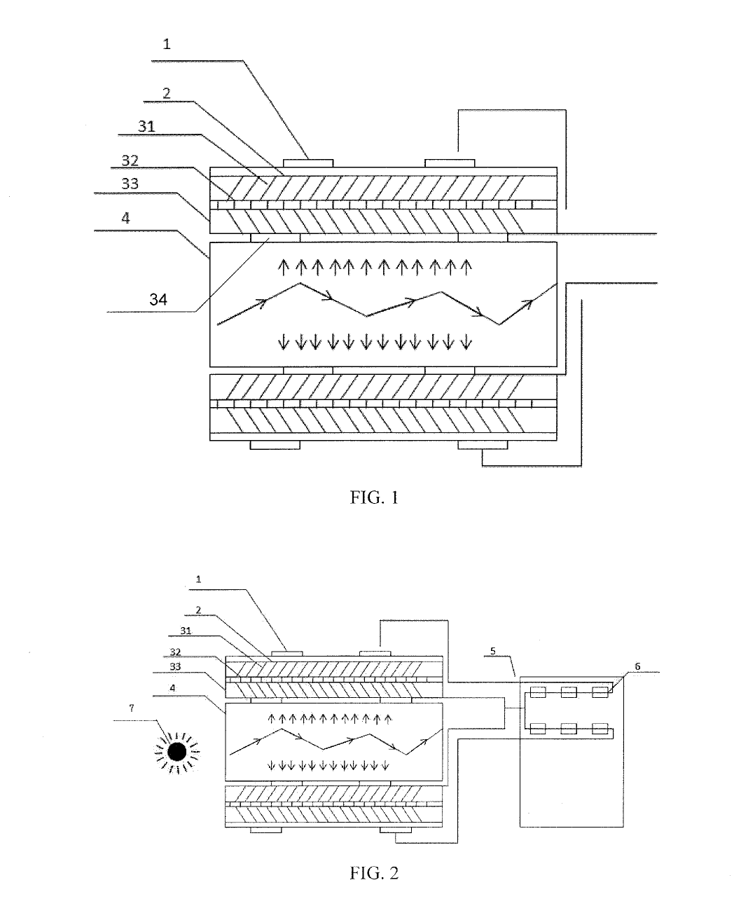

As illustrated in FIGS. 1-2, the photovoltaic device provided the first embodiment comprises at least one photovoltaic module including a photoelectric conversion sheet, the photoelectric conversion sheet takes the light guide plate 4 as a base, the light guide plate 4 introduces incident light into the photoelectric conversion sheet, and the photoelectric conversion sheet transforms the optical energy into electric energy by means of photovoltaic effect. In this way, by taking the light guide plate 4 as a base, the photovoltaic device has advantages of improved light yield, integration and simpler manufacture.

In some examples, the photovoltaic device provided by the first embodiment is integrated with photoelectric conversion sheets at both sides. That is to say, the photovoltaic module comprises two photoelectric conversion sheets which are provided at the upper and lower sides of the light guide plate 4, respectively, i.e., provided at two opposite primary surface sides of the light guide plate. The two photoelectric conversion sheets each take the light guide plate 4 as a base; the light guide plate 4 is used to introduce the incident light respectively into every photoelectric conversion sheets.

Further, the photovoltaic device also comprises a light emitting source 7 provided at the light incident side of the light guide plate 4, the light emitting source 7 shares the light guide plate 4 with the photoelectric conversion sheets. The light guide plate 4 can be used not only as the base for the photoelectric conversion sheets, but also can be integrated with the light emitting source 7 to achieve of the purpose of integral light-emitting.

Furthermore, the photovoltaic device also comprises a light-emitting diode 6 connected respectively with the photoelectric conversion sheet and the light guide plate 4, the light-emitting diode 6 can be driven to emit light using the current produced through photoelectric conversion, thereby achieving the purpose of conserving energy, saving electricity, and green ecology.

The basic principle of photoelectric conversion is based on the photovoltaic effect adjacent to the semiconductor heterojunction or the metal semiconductor interface, therefore also referred to as photovoltaic batteries. When photon incidents upon the photosensitive material, a electron-hole pair would be created by stimulate the inside of the material, then occurs separation under the action of electrostatic potential and is accumulated at the contact electrode 1, thus external circuit could have current passing therethrough. The photoelectric conversion also utilizes the photovoltaic effect, in which the organic material will absorb photon under the sunlight irradiation, if the photon has an energy greater than the band gap E of the organic material, exciton and electron-hole pair can be produced, the exciton has a binding energy of the order of 0.2˜1.0 eV, which is greater than the binding energy of the electron-hole pair produced by stimulating the corresponding inorganic semiconductor, therefore the exciton cannot dissociate automatically. Two kinds of materials, that have different electron affinity and ionizing potential, contact, and contact potential difference occurs at their contact interface and could drive the exciton to dissociate. When a Schottky battery is simply made by sandwiching a pure organic compound between two layers of metal electrodes 1, its efficiency is greatly lower. Afterwards, when a p-type semiconductor material donor and an n-type semiconductor material acceptor are joined together, it is found that highly effective exciton dissociation occurs at the interface between the two materials, that is what is called p-n heterojunction type photoelectric conversion.

Based on the above principle, the photoelectric conversion sheet in this embodiment comprises a n-type layer 33, a p-n junction 32, a p-type layer 31, a reflective layer 2 and a electrode 1 arranged on the light guide plate 4 in this order, that is, the n-type layer 33, the p-n junction 32, the p-type layer 31, the reflective layer 2 and the electrode 1 are provided on the light guide plate 4 from bottom to top in this order. Furthermore, the electrode 1 and the n-type layer 33 are connected with the light-emitting diode 6 through the conductive line 5, respectively. The incident light is irradiated on the photoelectric conversion sheet through the light guide plate 4, thus the photoelectric conversion sheet is provided with a light source and generates current which is supplied to the light-emitting diode 6.

Further, the surface of the light guide plate 4 is provided with multiple dot structures, so that the incident light is introduced into the upper photoelectric conversion sheet and the lower photoelectric conversion sheet along the dot structures.

It should be noted that, in the first embodiment, the materials for the light guide plate 4, the photoelectric conversion sheet, the reflective layer 2 and the electrode 1 are not restricted to a certain special form, but can be selected flexibly according to actual requirement.

As illustrated in the following exemplified embodiments: the material for the photoelectric conversion sheet comprises semiconductor material or inorganic compound molecular material or nano-crystalline material. For example: the photoelectric conversion sheet may be made from semiconductor silicon material, thus based on the semiconductor material, its operating principle is that the photoelectric material is used to absorb optical energy and then occurs photoelectric conversion reaction. Alternatively, it may also be inorganic salt compound, such as gallium arsenide III-V compound, multiple compound of cadmium copper indium selenium sulphide and the like, or it may also employ nano-crystalline photoelectric conversion. It is thus evident that the photoelectric conversion sheet is flexible in view of its material selection, thus benefiting massive production.

Furthermore, the material for the light guide plate 4 may be lithium niobate material, and multiple dot structures are provided at the surface of the light guide plate 4, so that the incident light generated by the light emitting source 7 is introduced into the two upper and lower photoelectric conversion sheets, respectively. Absolutely, the light guide plate 4 may also be of other light-transmitting polymeric materials, facilitating the molding and manufacture.

In some examples, the electrode 1 is a metal electrode, for example, gold electrode being used as the electrode 1, in electrical connection with the light-emitting diode 6. Furthermore, the reflective layer 2 is a metal reflective film, particularly being a silver reflective layer, thus improving the photovoltaic effect.

Optionally, a member 34 such as a spacer or adhesive can be further included between the n-type layer 33 of the photoelectric conversion sheet and the light guide plate. In addition, the photoelectric conversion sheet may further include an electrode at a side of the n-type layer 33 facing the light guide plate.

It can be seen that the photoelectric conversion sheet provided by the first embodiment is a kind of bilateral integral photoelectric conversion sheet affording improved light yield, integration, simpler fabrication and the like, which lays the foundation for the research of the small-sized energy-saving light emitting sources. As can be seen from the above-mentioned technical solutions, such a photovoltaic device has the following beneficial effects:

Firstly, the photoelectric conversion sheet can be used to achieve the purpose of conserving energy, saving electricity, and green ecology.

Secondly, the light guide plate can be used not only as the base for the photoelectric conversion sheets, but also as components of the light emitting source, to achieve of the purpose of integral light-emitting.

Thirdly, with the ease of integration of the photoelectric conversion sheet, it is possible to make the light emitting source even more compact while reaching the purpose of reducing power consumption.

Fourthly, the addition of the light guide plate realizes the integration of photoelectric conversion sheets at both sides, thereby improving the contact area of the incident light, it is thus possible to increase the photoelectric conversion efficiency.

### Second Embodiment

As illustrated in FIG. 3, the identical technical features between the first and second embodiments are omitted herein, the disclosure of the first embodiment also belongs to the disclosure of the second embodiment, and the second embodiment differs from the first embodiment in that the photovoltaic device provided by the second embodiment is a unilateral integrated photoelectric conversion sheet, i.e. the photoelectric conversion sheet being disposed at a single side of the light guide plate.

For example, the photovoltaic device comprises one photoelectric conversion sheet provided at the upper or lower side of the light guide plate 4. The photoelectric conversion sheet takes the light guide plate 4 as its base, the light guide plate 4 introduces the incident light into the photoelectric conversion sheet, and the photoelectric conversion sheet converts the optical energy into electric energy through photovoltaic effect. Of course, the light guide plate 4 of such a configuration may also be integrated with the light emitting source 7 to achieve the purpose of integral light-emitting.

It should be noted that, although the bilateral integral photoelectric conversion sheet in the first embodiment is an exemplary manner, the unilateral integrated photoelectric conversion sheet of the second embodiment also takes the light guide plate 4 as its base, and also has the advantages of improved light yield, integration and simpler manufacture. Therefore, the unilateral integrated photoelectric conversion sheet of the second embodiment also falls into the protective scope of the present disclosure. Other specific technical features have been described in detail hereinabove, its description is omitted here.

### Third Embodiment

This third embodiment also provides a display equipment comprising the photovoltaic device of the first or second embodiment. The photovoltaic device comprises at least one photovoltaic module including a photoelectric conversion sheet, and the number of the photoelectric conversion sheets is one or two, the photoelectric conversion sheet(s) takes the light guide plate 4 as its base, the light guide plate 4 introduces incident light into every photoelectric conversion sheet, and the photoelectric conversion sheet converts the optical energy into electric energy by means of photovoltaic effect. In this way, by taking the light guide plate 4 as a base, the photovoltaic device has advantages of improved light yield, integration and simpler manufacture.

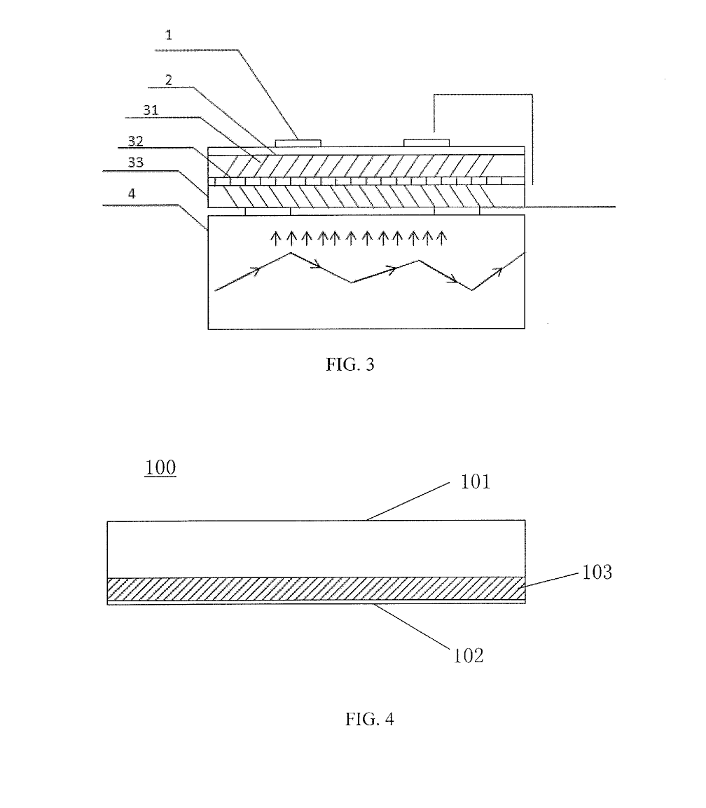

FIG. 4 illustrates a structural schematic view of a display equipment according to the present disclosure, for example. The display equipment 100 comprises a display side 101 and a back side 102 opposite to each other. In addition, the display equipment further comprises a photovoltaic device 103 which may also be provided within the display equipment at a location adjacent to the back side 102. The photovoltaic device 103 may be any one of the photovoltaic devices of the above embodiments. For example, the side section of the photovoltaic device 103 may be exposed from the side of the display equipment 100, so as to enable guiding the light into the light guide plate of the photovoltaic device 103 and into the photoelectric conversion sheet.

The display equipment of the third embodiment may be a mobile phone, a street lamp, an exhibition board or a bulletin board and similar structure employing such a photovoltaic device. Its advantages can be further set out taking the mobile phone as a preferable embodiment: due to the application of the photovoltaic device in such a mobile phone, the photoelectric conversion sheet can be used to convert the optical energy into the electric energy to charge the secondary battery of the mobile electronic equipment, thereby improving the endurance power of the mobile electronic equipment. What is more important, the mobile phone of the third embodiment does not need to be opened with a window at the rear cover of the mobile phone as compared with the prior art, which could ensure the wholeness of the rear cover of the electronic equipment, and such a mobile phone also does not need to be provided with a embed engagement structure any more, its configuration is simpler and thus reduces the thickness of the electronic equipment.

The above are only exemplary embodiments of the present invention, rather than limiting the protection reach of the present invention, the protection reach of the present invention is determined by the attached claims.

The present application claims the priority of the Chinese patent application No. 201610021236.2 filed on Jan. 13, 2016, the entirety of which is incorporated herein by reference as a part of the present application.

1. A photovoltaic device comprising at least one photoelectric conversion sheet and a light guide plate, the at least one photoelectric conversion sheet arranged at a light exiting face side of the light guide plate.

2. The photovoltaic device according to claim 1, wherein the photovoltaic device comprises two photoelectric conversion sheets provided at two opposite primary surface sides of the light guide plate, respectively.

3. The photovoltaic device according to claim 1, wherein the photovoltaic device comprises one photoelectric conversion sheet provided at one of the primary surface sides of the light guide plate.

4. The photovoltaic device according to claim 1, further comprising a light emitting source provided at a light incident side of the light guide plate.

5. The photovoltaic device according to claim 1, further comprising a light-emitting diode connected with the photoelectric conversion sheet.

6. The photovoltaic device according to claim 5, wherein the photoelectric conversion sheet comprises a n-type layer, a p-n junction, a p-type layer, a reflective layer and an electrode arranged on the light guide plate in this order; the electrode and the n-type layer are connected with the light-emitting diode through a conductive line, respectively.

7. The photovoltaic device according to claim 6, wherein the reflective layer is a metal reflective film.

8. The photovoltaic device according to claim 6, wherein the electrode is a metal electrode.

9. The photovoltaic device according to claim 1, wherein a material for the photoelectric conversion sheet is a semiconductor material or an inorganic compound molecular material or a nano-crystalline material.

10. The photovoltaic device according to claim 1, wherein the light guide plate is provided with multiple dot structures at its surface, so that the incident light transmits into the photoelectric conversion sheet along the dot structures.

11. The photovoltaic device according to claim 10, wherein a material for the light guide plate is a lithium niobate material.

12. A display equipment comprising the photovoltaic device according to claim 1.

13. The display equipment according to claim 12, wherein the photovoltaic device is provided inside the display equipment and a light incident side of the light guide plate of the photovoltaic device is exposed.

14. The display equipment according to claim 12, wherein the photovoltaic device comprises two photoelectric conversion sheets provided at two opposite primary surface sides of the light guide plate, respectively.

15. The display equipment according to claim 12, wherein the photovoltaic device comprises one photoelectric conversion sheet provided at one of the primary surface sides of the light guide plate.

16. The display equipment according to claim 12, further comprising a light emitting source provided at a light incident side of the light guide plate.

17. The display equipment according to claim 12, further comprising a light-emitting diode connected with the photoelectric conversion sheet.

18. The display equipment according to claim 17, wherein the photoelectric conversion sheet comprises a n-type layer, a p-n junction, a p-type layer, a reflective layer and an electrode arranged on the light guide plate in this order; the electrode and the n-type layer are connected with the light-emitting diode through a conductive line, respectively.

19. The display equipment according to claim 18, wherein the reflective layer is a metal reflective film.

20. The display equipment according to claim 18, wherein the electrode is a metal electrode.
